(19) United States
(12) Patent Application Publication
(10) Pub. No.: US 2018/0067524 A1
(43) Pub. Date: Mar. 8, 2018

(54) SUPPLEMENTAL AIR COOLING

(71) Applicant: Hewlett Packard Enterprise Development LP, Houston, TX (US)

(72) Inventors: David A. Moore, Tomball, TX (US); John p. Franz, Houston, TX (US); Wade D. Vinson, Magnolia, TX (US)

(21) Appl. No.: 15/562,063

(22) PCT Filed: Apr. 20, 2015
(86) PCT No.: PCT/US2015/026674

§ 371 Date: Sep. 27, 2017

(51) Int. Cl. G06F 1/20; H05K 7/20; H01L 23/467; H01L 23/40

(52) U.S. Cl. CPC G06F 1/20; G06F 1/203; H05K 7/20736; H01L 2023/4062; H01L 23/40; G06F 2200/201; H01L 23/467

(57) ABSTRACT

In one implementation, a system for supplemental air cooling includes a heat sink mounted to a computing device, a supplemental cooling device coupled to the heat sink by a number of heat pipes, and a fan coupled to the supplemental cooling device.

### BACKGROUND

Electronic devices (e.g., computing devices, computing hardware, etc.) can be utilized more efficiently within a particular temperature range. Some electronic devices can produce a relatively low quantity of heat or be less temperature sensitive compared to other electronic devices. Providing efficient cooling for electronic devices that are temperature sensitive or produce a relatively high quantity of heat can be important for maintaining the electronic devices.

Air cooling methods for cooling electronic devices can be limited by the thermal capacity of the air being utilized to cool the electronic devices and/or a thermal conductivity between the electronic devices and the air being utilized to cool the electronic devices. Increasing the cooling capacity and/or cooling efficiency of a system can require structural changes to the electronic devices and/or additions of other cooling methods (e.g., liquid cooling, etc.).

### BRIEF DESCRIPTION OF THE DRAWINGS

FIG. 1 illustrates a diagram of an example of a supplemental air cooling system consistent with the present disclosure.

FIG. 2 illustrates a diagram of an example of a supplemental air cooling system consistent with the present disclosure.

### DETAILED DESCRIPTION

A number of methods and systems for supplemental air cooling are described herein. In some examples, a system for supplemental air cooling can include a heat sink coupled to a computing device at a first location of a computing system, a supplemental cooling device coupled to a second location of the computing system, a number of heat pipes to couple the heat sink to the supplemental cooling device, and a fan coupled to the second location of the computing system. In some examples, the number of heat pipes can include or be supplemented with loop thermos-syphons, vapor chambers, or local liquid cooling solutions.

The supplemental air cooling system can be utilized to provide additional cooling resources to a computing system that includes a number of computing devices (e.g., central processing unit (CPU), graphics processing unit (GPU), etc.). In some examples, the computing system can include an existing cooling system such as an air cooling system that includes a number of fans to direct a flow of air past the number of computing devices. In these examples, the supplemental air cooling system can work with the existing cooling system to provide additional cooling capacity over utilizing only the existing cooling system.

The supplemental air cooling system can utilize a heat sink that is coupled or mounted directly to the computing devices that are producing heat. For example, the heat sink can be mounted to a top portion of a CPU to remove heat from the CPU. In some examples, the heat sink can be coupled to a supplemental cooling device by a number of heat pipes. The number of heat pipes can remove heat from the heat sink and transfer the heat to the supplemental cooling device. In some examples, the supplemental cooling device can be coupled to a different location of the computing system than the heat sink. Coupling the supplemental cooling device to a different location of the computing system can allow for more space utilization near the computing device.

In addition, coupling the supplemental cooling device to a different location can prevent serial flow of the air. That is, coupling the supplemental cooling device to a different location can prevent air from passing over the heat sink, removing heat from the heat sink, and then the warmer air also passing over the supplemental cooling device. The air utilized for cooling can have a thermal capacity that can limit the cooling capacity of the system when computing devices to be cooled are aligned in series. Thus, the supplemental air cooling system can increase the cooling capacity of the computing system by increasing cooling capacity without sacrificing space utilization of the computing system.

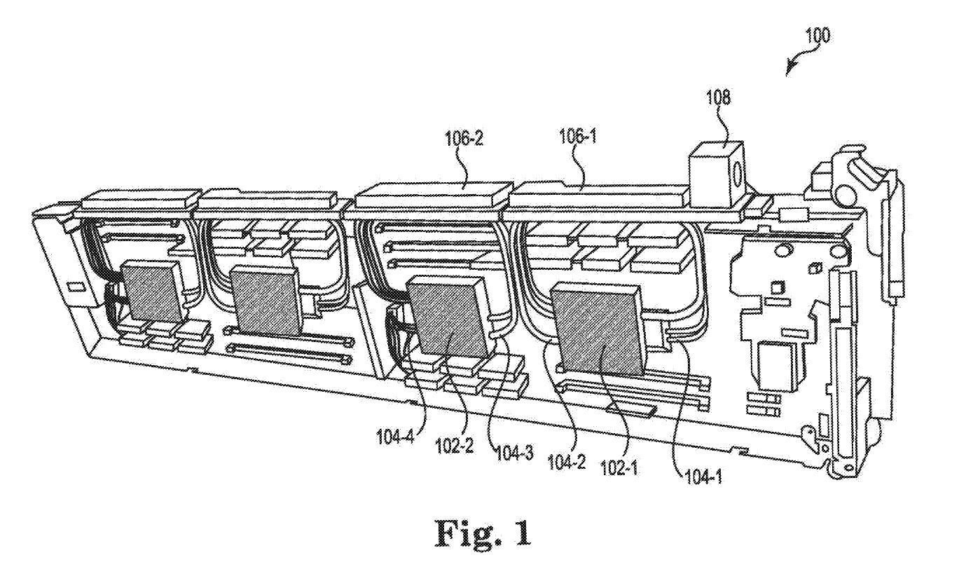

FIG. 1 illustrates a diagram of an example of a supplemental air cooling system 100 consistent with the present disclosure. The system 100 can be utilized with an existing cooling system utilized by the system 100. The system 100 can increase the cooling capacity of the computing system by removing heat from a number of computing devices (e.g., CPU, GPU, memory, voltage regulator module (VRM), etc.) and transferring the heat to a different location (e.g., area, etc.) of the computing system.

The system 100 can include a number of heat sinks 102-1, 102-2. The number of heat sinks 102-1, 102-2 can be coupled to a number of corresponding computing devices within the system 100. The number of heat sinks 102-1, 102-2 can be a passive heat exchanger that is in contact with the corresponding computing device. In some examples, the number of heat sinks 102-1, 102-2 can include a number of finned extended surfaces that can increase the surface area of the number of heat sinks 102-1, 102-2. Finned heat sinks attached at locations 102-1, 102-2 can remove a portion of the heat from the heat source (e.g., CPU, GPU, etc.), providing a number of finned extended surfaces that can be utilized to dissipate heat from the number of heat sinks 102-1, 102-2 to the air surrounding the number of heat sinks 102-1, 102-2.

The number of heat sinks 102-1, 102-2 can be coupled to a number of supplemental cooling devices 106-1, 106-2 via a number of heat pipes 104-1, 104-2. The number of heat pipes 104-1, 104-2 can be utilized to transfer heat from the number of heat sinks 102-1, 102-2 to the supplemental cooling devices 106-1, 106-2. In some examples, the number of heat pipes 104-1, 104-2 can include passive devices that utilize evaporation and condensation of a liquid within the heat pipes 104-1, 104-2. The number of heat pipes 104-1, 104-2 can be composed of a hollow copper tube with a wick structure and a relatively small quantity of water vapor sealed inside the heat pipes 104-1, 104-2. In some examples, the number of heat pipes 104-1, 104-2 can be sealed under a partial vacuum.

The number of heat pipes 104-1, 104-2 can function by receiving heat from the number of heat sinks 102-1, 102-2. The received heat from the number of heat sinks 102-1, 102-2 can cause the liquid within the heat pipes 104-1, 104-2 to evaporate from a wicking structure along the interior of the copper pipes within the number of heat pipes 104-1, 104-2. The vapor (e.g., evaporated liquid) can move from a position near the number of heat sinks 102-1, 102-2 towards the number of supplemental cooling devices 106-1, 106-2. Since the temperature near the supplemental cooling devices 106-1, 106-2 is relatively cooler than the temperature near the number of heat sinks 102-1, 102-2, the vapor can condense on the wicking structure. The condensed liquid on the wicking structure can move back towards the number of heat sinks 102-1, 102-2 via capillary action. When the condensed liquid moves back towards the number of heat sinks 102-1, 102-2, the relatively warmer temperature can cause the condensed liquid to evaporate again. This process of evaporation and condensation of the liquid can transfer the heat from the heat sinks 102-1, 102-2 to the number of supplemental cooling devices 106-1, 106-2.

The number of supplemental cooling devices 106-1, 106-2 can include a condenser plate to couple the number of heat pipes 104-1, 104-2. The condenser plate coupled to the number of heat pipes 104-1, 104-2 can promote condensation of the vapor within the number of heat pipes 104-1, 104-2 created by the heat from the number of heat sinks 102-1, 102-2. In some examples, the condenser plate can utilize a relatively large vapor inlet and a relatively small outlet to increase condensation of the vapor within the number of heat pipes 104-1, 104-2. In some examples, the condenser plate can utilize a liquid cooling system to maximize heat transfer from the number of heat pipes to the number of supplemental cooling devices 106-1, 1069-2.

In some examples, the number of supplemental cooling devices 106-1, 106-2 can be positioned and/or coupled to a different location than the number of heat sinks 102-1, 102-2. It can be advantageous to couple the number of supplemental cooling devices 106-1, 106-2 to a different location so that more valuable space closer to the computing devices (e.g., space at a closer distance to computing devices, etc.) can be utilized for other computing resources (e.g., additional CPUs, additional GPUs, memory, etc.). That is, the distance between computing resources can be reduced to provide attendant reduction of electrical signal propagation delays. The other computing resources can provide greater efficiency if they are located at a relatively closer position to the number of computing devices. Thus, the system 100 can provide greater cooling capacity without occupying additional space that is closer to the number of computing devices.

In some examples, the system can include a fan 108. The fan 108 can be utilized to direct a flow of air across the number of supplemental cooling devices 106-1, 106-2. For example, the fan 108 can be utilized to direct a flow of air across in a relatively straight line from a front position to a rear position of the system 100. The position of the fan 108 can be altered based on an existing air cooling system that is utilized to cool the system 100. For example, an existing air cooling system can be utilized to direct a flow of cool air past the system 100. In this example, the cool air can be utilized to remove heat from the number of computing devices within the system 100.

In some examples, the number of supplemental cooling devices 106-1, 106-2 can include a number of finned extended surfaces that can be utilized to dissipate heat from the number of supplemental cooling devices 106-1, 106-2. In some examples, heat can be transferred from the finned extended surfaces into the air moving past the finned surfaces. In some examples, the fan 108 can provide the moving air past the finned surfaces. In some examples, a dry disconnect docking surface can be used to couple finned extended surfaces to the supplemental cooling devices 106-1, 106-2. For example, some systems can include an air cooled service bay that can be utilized for a single server blade. In this example, the chassis can include a tray slot and clamping mechanism that can be used as dry disconnect docking surface to couple finned extended surfaces.

The system 100 can allow supplemental cooling for computing systems that include relatively tightly packed computing devices and/or computing hardware. That is, the system 100 can provide additional cooling capacity for computing systems that have limited space for a supplemental cooling system. Thus, the system 100 can be implemented on a number of different computing systems with minimal redesign of the computing system.

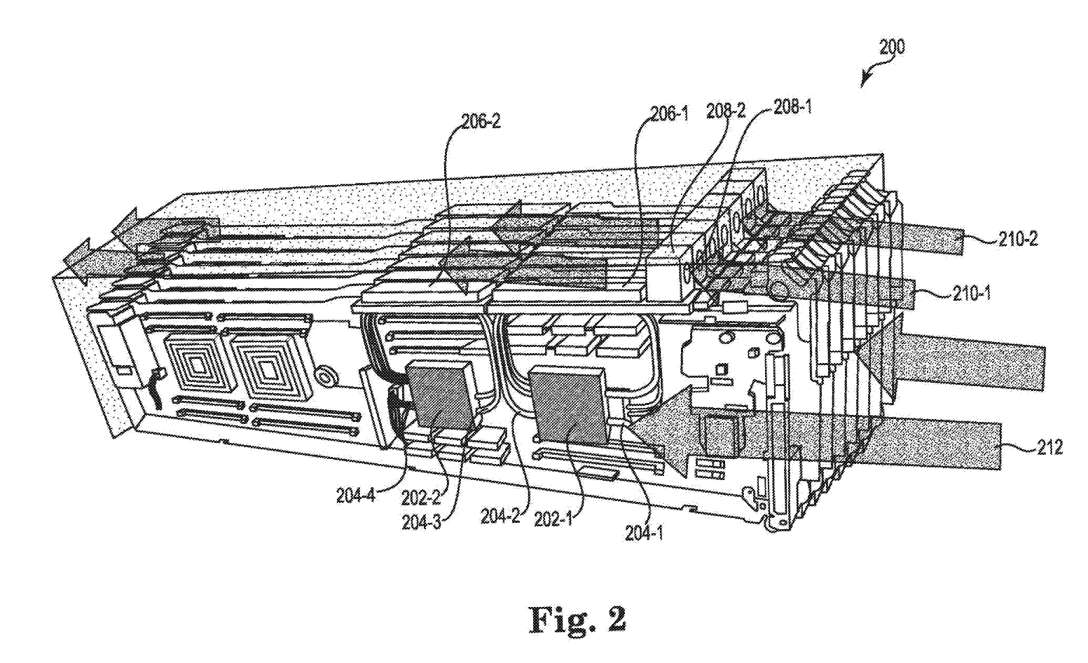

FIG. 2 illustrates a diagram of an example of a supplemental air cooling system 200 consistent with the present disclosure. The system 200 can provide additional cooling capacity for a computing system that includes a number of computing devices (e.g., central processing unit (CPU), graphics processing unit (GPU), etc.). The system 200 can provide the additional cooling capacity for the computing system utilizing relatively less valuable space compared to previous systems and methods.

The system 200 can include the same and/or similar devices as the system 100 as referenced in FIG. 1. The system 200 can include a number of heat sinks 202-1, 202-2 that are coupled to a number of computing devices. For example, the number of heat sinks 202-1, 202-2 can be coupled to a top portion of a number of corresponding GPUs. As described herein, the heat sinks 202-1, 202-2 can include a number of finned extended surfaces. The number of finned extended surfaces can be utilized to increase a surface area of the heat sinks 202-1, 202-2. The increased surface area can be utilized to transfer heat from the heat sinks 202-1, 202-2 to air near the number of heat sinks 202-1, 202-2.

In some examples, the number of heat sinks 202-1, 202-2 can be located at a first location within the system 200. The first location can include an air channel 212 that directs a flow of air over the number of heat sinks 202-1, 202-2. In some examples, the air channel 212 can include baffles (e.g., brackets, physical brackets, physical barriers, etc.) to separate the air channel 212 from other air channels (e.g., air channel 210-1, air channel 210-2, etc.). In some examples, the air channel 212 can utilize air flow from an existing air cooling system that is coupled to the system 200.

The number of heat sinks 202-1, 202-2 can be coupled to a number of supplemental cooling devices 206-1, 206-2 via a number of heat pipes 204-1, 204-2. As described herein, the number of heat pipes 204-1, 204-2 can be utilized to transfer heat from the number of heat sinks 202-1, 202-2 to the number of supplemental cooling devices 206-1, 206-2. In some examples, the number of heat pipes 204-1, 204-2 can utilize a system of condensation and evaporation of a liquid within the number of heat pipes 204-1, 204-2 to transfer heat from the number of heat sinks 202-1, 202-2 to the number of supplemental cooling devices 206-1, 206-2.

The number of supplemental cooling devices 206-1, 206-2 can include a condenser plate to couple the number of heat pipes 204-1, 204-2. The condenser plate coupled to the number of heat pipes 204-1, 204-2 can promote condensation of the vapor within the number of heat pipes 204-1, 204-2 created by the heat from the number of heat sinks 202-1, 202-2. In some examples, the number of supplemental cooling devices 206-1, 206-2 can be coupled to the computing system at a second location that is different than the first location where the heat sinks 202-1, 202-2 are coupled. The second location can be an exterior position of a number of printed circuit boards (PCBs) of the computing system. By coupling the number of supplemental cooling devices 206-1, 206-2 to an exterior position, valuable space near the computing devices of the PCB can be utilized for other computing devices and not for cooling devices.

The exterior position of the computing system that includes the number of supplemental cooling devices 206-1, 206-2 can include a number of air channels 210-1, 210-2. The number of air channels 210-1, 210-2 can include a number of physical baffles that separate the number of supplemental cooling devices 206-1, 206-2. In some examples, the number of supplemental cooling devices 206-1, 206-2 can be separated into parallel air channels 210-1, 210-2. In some examples, a number of fans 208-1, 208-2 can be positioned at each of the number of air channels 210-1, 210-2.

The number of fans 208-1, 208-2 can be coupled to the second location at or near the exterior position of the computing system near the number of supplemental cooling devices 206-1, 206-2. The number of fans 208-1, 208-2 can receive air from an existing air cooling system in a similar manner as the air channel 212. The number of fans 208-1, 208-2 can be utilized to increase or decrease air flow over the number of supplemental cooling devices 206-1, 206-2.

In one example, the system 200 can include a number of heat sinks 202-1, 202-2 each coupled to a number of computing devices, a number of supplemental cooling devices 206-1, 206-2 coupled to each of the number of heat sinks 202-1, 202-2 by a number of heat pipes 204-1, 204-2, wherein the number of supplemental cooling devices 206-1, 206-2 are separated by a plurality of air channels 210-1, 210-2, and a number of fans 208-1, 208-2 coupled to each of the plurality of air channels 210-1, 210-2. In this example, the number of fans 208-1, 208-2 can be coupled to the air channels 210-1, 210-2 by a number of baffles as described herein. In some examples, the number of heat sinks 202-1, 202-2 can include a number of finned extended surfaces to remove heat from the heat sinks 202-1, 202-2 to an area separated from the number of supplemental cooling devices (e.g., air channel 212, etc.).

The system 200 can allow supplemental cooling for computing systems that include relatively tightly packed computing devices and/or computing hardware. That is, the system 200 can provide additional cooling capacity for computing systems that have limited space for a supplemental cooling system. Thus, the system 200 can be implemented on a number of different computing systems with minimal redesign of the computing system.

As used herein, “a” or “a number of” something can refer to one or more such things. For example, “a number of widgets” can refer to one or more widgets. The above specification, examples and data provide a description of the method and applications, and use of the system and method of the present disclosure. Since many examples can be made without departing from the spirit and scope of the system and method of the present disclosure, this specification merely sets forth some of the many possible example configurations and implementations.

What is claimed is:

1. A system for supplemental air cooling, comprising:
a heat sink mounted to a computing device;
a supplemental cooling device coupled to the heat sink by a number of heat pipes; and
a fan coupled to the supplemental cooling device.

2. The system of claim 1, wherein the number of heat pipes comprise a passive device that utilizes a combination of evaporation and condensation within a partial vacuum.

3. The system of claim 1, wherein the heat sink includes a number of finned extended surfaces.

4. The system of claim 1, wherein the supplemental cooling device includes a condenser plate to couple the number of heat pipes.

5. The system of claim 4, wherein the condenser plate includes a number of finned extended surfaces.

6. The system of claim 1, comprising an air cooling channel to the supplemental cooling device.

7. The system of claim 6, wherein the air cooling channel separates the supplemental cooling device from a number of additional cooling devices.

8. The system of claim 6, wherein the air cooling channel separates the heat sink from the supplemental cooling device.

9. A system for supplemental air cooling, comprising:
a heat sink coupled to a computing device at a first location of a computing system;
a supplemental cooling device coupled to a second location of the computing system;
a number of heat pipes to couple the heat sink to the supplemental cooling device; and
a fan coupled to the second location of the computing system.

10. The system of claim 9, wherein the fan is directed to the supplemental cooling device.

11. The system of claim 9, comprising a first air channel to encase the first location of the computing system and a second air channel to encase the second location of the computing system.

12. The system of claim 11, wherein the first air channel and the second air channel separate the first location and the second location of the computing system.

13. A system for supplemental air cooling, comprising:
a number of heat sinks each coupled to a number of computing devices;
a number of supplemental cooling devices coupled to each of the number of heat sinks by a number of heat pipes, wherein the number of supplemental cooling devices are separated by a plurality of air channels; and
a number of fans coupled to each of the plurality of air channels.

14. The system of claim 13, wherein the plurality of air channels separate the number of supplemental cooling devices from the number of heat sinks.

15. The system of claim 13, wherein the number of heat sinks include a number of finned extended surfaces to remove heat from the heat sinks to an area separated from the number of supplemental cooling devices.
